(19) United States
(12) Patent Application Publication
(10) Pub. No.: US 2026/0068569 A1
(43) Pub. Date: Mar. 5, 2026

(54) SUBSTRATE TREATMENT METHOD AND SUBSTRATE TREATMENT DEVICE

(71) Applicant: SCREEN Holdings Co., Ltd., Kyoto (JP)

(72) Inventor: Yasuyuki MATSUNAGA, Kyoto (JP)

(21) Appl. No.: 19/106,777

(22) PCT Filed: Jun. 22, 2023
(86) PCT No.: PCT/JP2023/023084

§ 371 Date: Feb. 26, 2025

(30) Foreign Application Priority Data
Aug. 26, 2022 (JP) 2022-134829

(51) Int. Cl. H01L 21/3213; H01L 21/67

(52) U.S. Cl. CPC H01L 21/32134

(57) ABSTRACT

A substrate processing method includes immersing a substrate in an alkaline processing liquid and etching, by the processing liquid, a polysilicon layer filled in a recess portion of columnar shape extending substantially perpendicular to a principal surface of the substrate, and in etching the polysilicon layer, bubbles generated inside the recess portion are removed.

### TECHNICAL FIELD

The present invention relates to a substrate processing method and a substrate processing apparatus.

### BACKGROUND ART

Conventionally, there is known a substrate processing method of processing a substrate with an alkaline processing liquid (see, for example, Patent Literature 1). A substate processing method of performing etching using an alkaline etching solution on a substrate having a laminated film that includes a plurality of polysilicon films and a plurality of silicon oxide films is described in Patent Literature 1. A recess portion penetrating through the laminated film in a thickness direction is formed in the substrate described in Patent Literature 1. The recess portion is a cavity, and the polysilicon films and the silicon oxide films are exposed at an inner side surface of the recess portion. By processing the substrate with the alkaline etching solution, the polysilicon films are etched selectively. That is, in Patent Literature 1, the plurality of polysilicon films are etched radially outward with the recess portion as a center.

### CITATION LIST

### Patent Literature

Patent Literature 1: Japanese Patent Application Publication No. 2021-136429

### SUMMARY OF INVENTION

### Technical Problem

Incidentally, in accompaniment with the miniaturization, etc., of elements formed on a semiconductor substrate in recent years, recess portion portions of high aspect ratio are formed, for example, in a NAND element, etc. The recess portion portions extend substantially perpendicular to principal surface of the substrate.

Upon examining variously, the present inventor found that etching failure occurs in some cases where a polysilicon layer filled in a recess portion of high aspect ratio is etched with an alkaline processing liquid. Specifically, by reaction of the polysilicon layer and the processing liquid, bubbles of hydrogen are generated and the generated bubbles join together to become large and clog the recess portion. It was found that fresh processing liquid therefore cannot reach the polysilicon layer and the polysilicon layer remains inside the recess portion.

The present inventor also made the following finding as a result of diligent examination. Specifically, when a recess portion with laminated polysilicon films and silicon oxide films exposed at an inner side surface is processed with an alkaline processing liquid as in Patent Literature 1 mentioned above, etching failure does not occur. A reason for this is considered to be as follows. A surface (polysilicon film surface) that is etched by the processing liquid is of an elongate band shape. On the other hand, when bubbles generated by etching join together, the bubbles tend to deform into a spherical shape. Therefore, when the bubbles enlarge by joining together, a portion of the bubbles separate from the polysilicon film surface. The bubbles are then released from inside the recess portion. The processing liquid can thus reach the polysilicon film surface and therefore, etching failure does not occur.

The present invention has been made in view of the above problem and an object thereof is to provide a substrate processing method and a substrate processing apparatus by which occurrence of etching failure can be suppressed.

### Solution to Problem

According to one aspect of the present invention, a substrate processing method includes an immersion step of immersing a substrate in an alkaline processing liquid and an etching step of etching, by the processing liquid, a polysilicon layer filled in a recess portion of columnar shape extending substantially perpendicular to a principal surface of the substrate, and in the etching step, bubbles generated inside the recess portion are removed.

With the substrate processing method of the present invention, preferably in the etching step, the bubbles generated inside the recess portion are removed in accordance with a silicon concentration in the processing liquid.

With the substrate processing method of the present invention, preferably in the etching step, the bubbles clogged in the recess portion are removed.

With the substrate processing method of the present invention, preferably in the etching step, the processing liquid and the bubbles are removed from inside the recess portion by draining the processing liquid from a processing tank storing the processing liquid or drawing up the substrate from the processing tank.

With the substrate processing method of the present invention, preferably in the etching step, the bubbles generated inside the recess portion are removed by supplying a gas below the substrate and generating bubbles inside the processing liquid.

With the substrate processing method of the present invention, preferably in the etching step, the bubbles generated inside the recess portion are removed by applying an ultrasonic vibration to the processing liquid.

With the substrate processing method of the present invention, the processing liquid preferably contains tetramethylammonium hydroxide.

According to another aspect of the present invention, a substrate processing apparatus includes a substrate holding portion, a processing tank, and a controlling portion. The substrate holding portion holds at least one substrate. The processing tank stores an alkaline processing liquid for immersing the substrate held by the substrate holding portion. The substrate includes a principal surface, a recess portion of columnar shape extending substantially perpendicular to the principal surface, and a polysilicon layer filled in the recess portion. The controlling portion immerses the substrate, held by the substrate holding portion, in the processing liquid such that the polysilicon layer is etched by the processing liquid. The controlling portion removes bubbles generated inside the recess portion.

In the substrate processing apparatus of the present invention, preferably the controlling portion removes the bubbles, generated inside the recess portion, in accordance with a silicon concentration in the processing liquid.

Preferably in the substrate processing apparatus of the present invention, the controlling portion removes the bubbles clogged in the recess portion.

Preferably in the substrate processing apparatus of the present invention, the controlling portion drains the processing liquid from the processing tank or draws up the substrate from the processing tank to remove the processing liquid and the bubbles from inside the recess portion.

The substrate processing apparatus of the present invention preferably further includes a bubble generating portion that supplies a gas to the processing liquid and makes bubbles be generated in the processing liquid and the controlling portion controls the bubble generating portion such that the gas is supplied below the substrate and the bubbles are generated inside the processing liquid.

The substrate processing apparatus of the present invention preferably further includes an ultrasonic generating portion that applies an ultrasonic vibration to the processing liquid and the controlling portion controls the ultrasonic generating portion to apply the ultrasonic vibration to the processing liquid.

In the substrate processing apparatus of the present invention, the processing liquid preferably contains tetramethylammonium hydroxide.

### Advantageous Effect(s) of Invention

According to the present invention, a substrate processing method and a substrate processing apparatus by which occurrence of etching failure can be suppressed can be provided.

### BRIEF DESCRIPTION OF DRAWINGS

FIGS. 1(a) and (b) are schematic perspective views showing a substrate processing apparatus according to a first preferred embodiment of the present invention.

FIG. 2 is a schematic view showing the substrate processing apparatus according to the first preferred embodiment.

FIG. 3 is an enlarged sectional view schematically showing the structure of a substrate processed using the substrate processing apparatus of the first preferred embodiment.

FIG. 4 is an enlarged sectional view schematically showing a state in which bubbles are generated inside a recess portion.

FIG. 5 is an enlarged sectional view schematically showing a state in which the bubbles generated inside the recess portion become enlarged.

FIG. 6 is a flowchart showing a substrate processing method according to the first preferred embodiment.

FIG. 7 is a flowchart for describing step S2 in detail.

FIG. 8 is a flowchart for describing step S23 in detail.

FIG. 9 is an enlarged sectional view schematically showing a state in which a processing liquid has been drained from inside the recess portion.

FIG. 10 is an enlarged sectional view schematically showing a state in which the processing liquid has flowed into the recess portion.

FIG. 11 is a flowchart for describing step S23 of a substrate processing method of a first modification example of the first preferred embodiment in detail.

FIG. 12 is a schematic view showing the structure of a substrate processing apparatus according to a second preferred embodiment of the present invention.

FIG. 13 is an enlarged sectional view schematically showing flows of the processing liquid and the bubbles in a periphery of a recess portion.

FIG. 14 is a flowchart for describing step S23 of a substrate processing method of the second preferred embodiment of the present invention in detail.

FIG. 15 is a schematic view showing the structure of a substrate processing apparatus according to a third preferred embodiment of the present invention.

FIG. 16 is an enlarged sectional view schematically showing a state in which an ultrasonic vibration propagates in a periphery of a recess portion.

FIG. 17 is an enlarged sectional view schematically showing a state in which a bubble is split by the ultrasonic vibration in the periphery of the recess portion.

FIG. 18 is a flowchart for describing step S23 of a substrate processing method of the third preferred embodiment of the present invention in detail.

### DESCRIPTION OF EMBODIMENTS

Preferred Embodiments of the Present Invention shall now be described with reference to the drawings. In the figures, same or corresponding portions are provided with the same reference sign and description shall not be repeated. Also, in the preferred embodiments of the present invention, an X-axis, a Y-axis, and a Z-axis are orthogonal to each other, the X-axis and the Y-axis are parallel to horizontal directions and the Z-axis is parallel to a vertical direction.

### First Preferred Embodiment

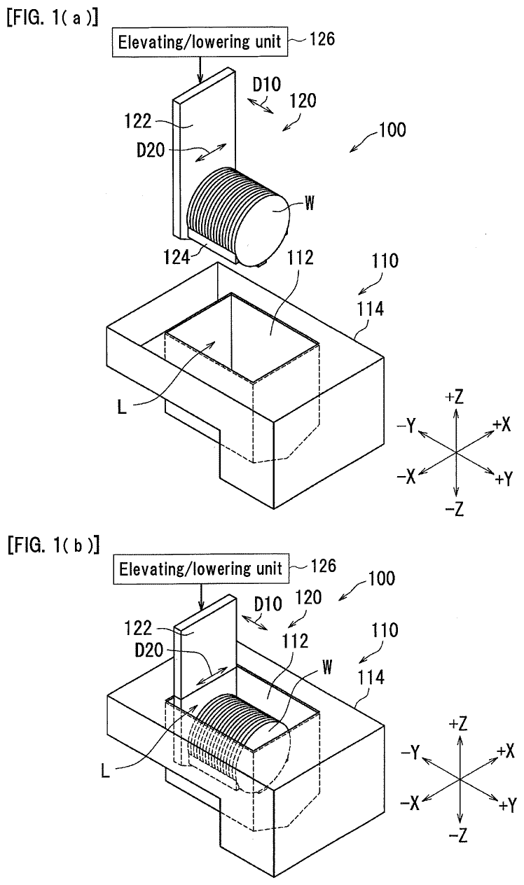

A substrate processing apparatus 100 and a substrate processing method according to a first preferred embodiment of the present invention shall be described with reference to FIG. 1 to FIG. 10. First, the substrate processing apparatus 100 shall be described with reference to FIG. 1. FIG. 1 shows schematic perspective views showing the substrate processing apparatus 100. Specifically, FIG. 1(a) is a schematic perspective view before immersion of substrates W in a processing liquid L inside a processing tank 110 and FIG. 1(b) is a schematic perspective view after immersion of the substrates W in the processing liquid L inside the processing tank 110.

As shown in FIG. 1(a) and FIG. 1(b), the substrate processing apparatus 100 processes a plurality of the substrates W in a batch by the processing liquid L. The substrate processing apparatus 100 is a substrate processing apparatus of a so-called batch type. Here, the substrate processing apparatus 100 may process many substrates W of a predetermined number at a time by the processing liquid L. The predetermined number is an integer not less than 1.

Each substrate W is of a thin plate shape. Typically, the substrate W is of a thin, substantially disk shape. The substrate W includes a semiconductor wafer, a substrate for a liquid crystal display, a substrate for a plasma display, a substrate for a field emission display (FED), a substrate for an optical disc, a substrate for a magnetic disc, a substrate for a magneto-optical disc, a substrate for a photomask, a ceramic substrate, a substrate for a solar cell, etc.

By the processing liquid L, at least one among etching, surface processing, characteristic imparting, processing film forming, removing of at least a portion of a film, and cleaning is performed on the plurality of substrates W. In this preferred embodiment, the substrate processing apparatus 100 applies etching of a polysilicon layer to a surface at a pattern forming side (hereinafter indicated at times as a principal surface Wa) of each substrate W constituted of a silicon substrate. In such etching, the polysilicon layer is removed from the surface of the substrate W.

The processing liquid L is, for example, a chemical liquid. The processing liquid contains, for example, phosphoric acid (H₃PO₄), a liquid mixture in which ammonia, hydrogen peroxide water, and water are mixed, or tetramethylammonium hydroxide. In this preferred embodiment, an alkaline processing liquid is used as the processing liquid L. Also, in this preferred embodiment, the processing liquid L contains tetramethylammonium hydroxide. When an alkaline processing liquid containing tetramethylammonium hydroxide, etc., is used as the processing liquid L, the polysilicon layer is removed from the surface of the substrate W. In other words, a solution of high temperature and high alkali concentration that does not contain an impurity is used as the processing liquid L and the processing liquid L dissolves silicon (Si⁴⁺). Here, a temperature of the processing liquid L is not restricted in particular.

Also, although an example in which the processing liquid L contains tetramethylammonium hydroxide shall be described with this preferred embodiment, the type of processing liquid L is not restricted in particular as long as the substrate W can be processed. For example, the alkaline processing liquid L may contain a quaternary ammonium hydroxide. As the quaternary ammonium hydroxide, for example, tetramethylammonium hydroxide (TMAH), tetraethylammonium hydroxide (TEAH), tetrapropylammonium hydroxide, and tetrabutylammonium hydroxide can be cited. Among these quaternary ammonium hydroxides, especially, it is most favorable to use tetramethylammonium hydroxide from a reason of being high in etching rate with respect to silicon.

The substrate processing apparatus 100 includes a processing tank 110 and a substrate holding portion 120.

The processing tank 110 stores the processing liquid L. Specifically, the processing tank 110 stores the processing liquid L. Specifically, the processing tank 110 has a double tank structure including an inner tank 112 and an outer tank 114. The inner tank 112 and the outer tank 114 each have an upper opening that opens upward. The inner tank 112 is arranged to store the processing liquid L and be capable of housing the plurality of substrates W. The outer tank 114 is provided at an outer circumferential surface of the upper opening of the inner tank 112.

The substrate holding portion 120 holds the plurality of substrates W. The plurality of substrates W are arrayed in a single column along a first direction D10 (Y direction). In other words, the first direction D10 indicates an array direction of the plurality of substrates W. The first direction D10 is substantially parallel to a horizontal direction. Also, each of the plurality of substrates W is substantially parallel to a second direction D20. The second direction D20 is substantially orthogonal to the first direction D10 and is substantially parallel to a horizontal direction.

Specifically, the substrate holding portion 120 includes a lifter. The substrate holding portion 120 moves vertically upward or vertically downward in a state of holding the plurality of substrates W. By the substrate holding portion 120 moving vertically downward, the plurality of substrates W held by the substrate holding portion 120 are immersed in the processing liquid L stored in the inner tank 112.

In FIG. 1(a), the substrate holding portion 120 is positioned above the inner tank 112 of the processing tank 110. The substrate holding portion 120 descends vertically downward (in a −Z direction) while holding the plurality of substrates W. The plurality of substrates W are thereby loaded in the processing tank 110.

When, as shown in FIG. 1(b), the substrate holding portion 120 descends down to the processing tank, the plurality of substrates W become immersed in the processing liquid L inside the processing tank 110. In the first preferred embodiment, the substrate holding portion 120 immerses the plurality of substrates W aligned at predetermined intervals into the processing liquid L stored in the processing tank 110.

In detail, the substrate holding portion 120 further includes a main body plate 122 and holding rods 124. The main body plate 122 is a plate that extends in the vertical direction (Z direction). The holding rods 124 extend in a horizontal direction (Y direction) from a principal surface at one side of the main body plate 122. In the example of FIG. 1(a) and FIG. 1(b), three holding rods 124 extend in the horizontal direction from the principal surface at one side of the main body plate 122. The plurality of substrates W are held in an upright orientation (vertical orientation) in a state of being aligned at the predetermined intervals with a lower edge of each substrate W being put in contact with the plurality of the holding rods 124.

The substrate holding portion 120 may further include an elevating/lowering unit 126. The elevating/lowering unit 126 elevates and lowers the main body plate 122 between a processing position (position shown in FIG. 1(b)) at which the plurality of substrates W held by the substrate holding portion 120 are positioned inside the inner tank 112 and a retreat position (position shown in FIG. 1(a)) at which the plurality of substrates W held by the substrate holding portion 120 are positioned above the inner tank 112. Therefore, by the main body plate 122 being moved to the processing position by the elevating/lowering unit 126, the plurality of substrates W held by the holding rods 124 are immersed in the processing liquid L.

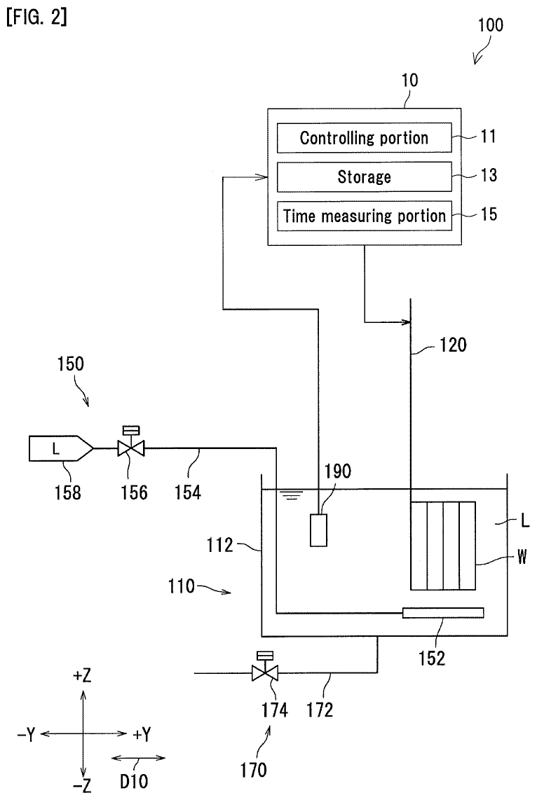

Next, the substrate processing apparatus 100 shall be described further with reference to FIG. 2. FIG. 2 is a schematic view showing the substrate processing apparatus 100 according to the first preferred embodiment.

As shown in FIG. 2, the substrate processing apparatus 100 further includes a processing liquid supplying portion 150, a draining portion 170, and a concentration meter 190.

The processing liquid supplying portion 150 supplies the processing liquid L to the processing tank 110. The processing liquid supplying portion 150 includes a nozzle 152, a piping 154, a valve 156, and a processing liquid supply source 158. The nozzle 152 discharges the processing liquid L to the inner tank 112. The nozzle 152 is not restricted in position in particular and, for example, is disposed inside the inner tank 112. Also, the nozzle 152 may be disposed, for example, above the inner tank 112 instead. In this preferred embodiment, the nozzle 152 is disposed below the substrates W and discharges the processing liquid L upward. The nozzle 152 is connected to the piping 154. The processing liquid L from the processing liquid supply source 158 is supplied to the piping 154. The valve 156 is disposed in the piping 154. The valve 156 opens and closes the piping 154. When the valve 156 is opened, the processing liquid L is supplied from the processing liquid supply source 158 into the inner tank 112 via the piping 154.

The draining portion 170 drains the processing liquid L in the processing tank 110. Specifically, the draining portion 170 includes a drain piping 172 and a valve 174. And the drain piping 172 is connected to a bottom wall of the inner tank 112 of the processing tank 110. The valve 174 is disposed in the drain piping 172. The valve 174 opens and closes the drain piping 172. By opening the valve 174, the processing liquid L stored inside the inner tank 112 is drained to an exterior through the drain piping 172. The drained processing liquid L is fed to a drain processing apparatus (not shown).

The concentration meter 190 measures a concentration of the processing liquid L. In this preferred embodiment, the concentration meter 190 detects a silicon concentration contained in the processing liquid L. At least a portion of the concentration meter 190 is disposed inside the processing liquid L. The concentration meter 190 transmits a measurement result to a controlling portion 11 described below. Also, the concentration meter 190 may detect a concentration of the tetramethylammonium hydroxide in the processing liquid L instead.

Next, the controller 10 shall be described. The substrate processing apparatus 100 further includes the controller 10.

The controller 10 controls respective components of the substrate processing apparatus 100. For example, the controller 10 controls the substrate holding portion 120, the processing liquid supplying portion 150, and the draining portion 170. The controller 10 is, for example, a computer. In detail, the controller 10 incudes a controlling portion 11, a storage 13, and a time measuring portion 15.

The controlling portion 11 includes a processor, for example, a CPU (central processing unit), etc.

The storage 13 stores data and a computer program. The storage 13 includes, for example, a main storage and an auxiliary storage. The main storage includes, for example, a semiconductor memory. The auxiliary storage includes, for example, a semiconductor memory, a solid state drive, and/or a hard disk drive.

The time measuring portion 15 measures time. The time measuring portion 15 is, for example, a timer.

The controlling portion 11 controls the substrate holding portion 120, the processing liquid supplying portion 150, and the draining portion 170. Also, the controlling portion 11 controls the processing liquid supplying portion 150 and the draining portion 170. Specifically, the controlling portion 11, for example, controls the draining portion 170 such that the processing liquid L is drained from the processing tank 110 in accordance with the detection result from the concentration meter 190. Also, the controlling portion 11 controls the processing liquid supplying portion 150 such that the processing liquid L is supplied to the processing tank 110. That is, the controlling portion 11, for example, replaces the processing liquid L inside the processing tank 110 in accordance with the detection result from the concentration meter 190. The controlling portion 11, for example, may replace the processing liquid L inside the processing tank 110 when the silicon concentration of the processing liquid L becomes a predetermined value or more or may replace the processing liquid L inside the processing tank 110 when the concentration of the tetramethylammonium hydroxide of the processing liquid L becomes less than a predetermined value.

In this preferred embodiment, the controlling portion 11, for example, controls the substrate holding portion 120 or the draining portion 170 such that the processing liquid L is released from recess portion portions Wb, to be described below, of the substrates W in accordance with the detection result from the concentration meter 190. More specifically, when a polysilicon layer Wc, to be described below, is etched by the processing liquid L, the silicon concentration in the processing liquid L increases. Based on the detection result from the concentration meter 190, the controlling portion 11 calculates an increase amount of the silicon concentration contained in the processing liquid L. Then, in this preferred embodiment, when an increase amount per unit time of the silicon concentration becomes a predetermined value or less, the controlling portion 11 moves the substrate holding portion 120 vertically upward to draw out the substrates W from the processing liquid L. By the controlling portion 11 drawing out the substrates W from the processing liquid L, the processing liquid L is released from the recess portion portions Wb, to be described below, of the substrates W.

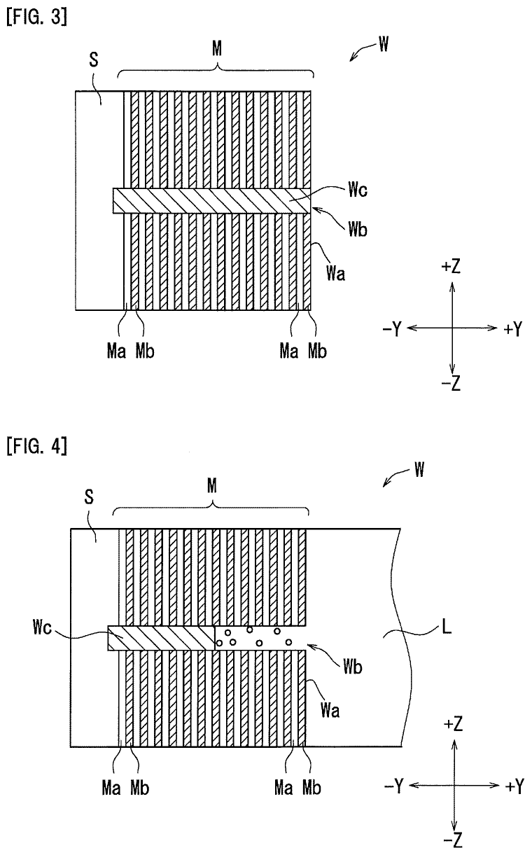

Next, the structure of a substrate W processed using the substrate processing apparatus 100 of the first preferred embodiment shall be described with reference to FIG. 3. FIG. 3 is an enlarged sectional view schematically showing the structure of the substrate W processed using the substrate processing apparatus 100 according to the first preferred embodiment. As shown in FIG. 3, the substrate W includes the principal surface Wa, the recess portion Wb of columnar shape extending substantially perpendicular to the principal surface Wa, and the polysilicon layer Wc filled inside the recess portion Wb. A plurality (large number) of the recess portion portions Wb are formed. The polysilicon layer Wc is formed by an interior of the recess portion Wb being filled with polysilicon. The polysilicon is soluble in the processing liquid L

In detail, the substrate W has a base material S and a laminated structure M. The laminated structure M has, for example, a structure in which silicon oxide films Ma and silicon nitride films Mb are laminated alternately in large numbers. The laminated structure M is disposed at a surface at one side of the base material S. The laminated structure M extends in a +Y direction from the surface at one side of the base material S. Here, the silicon oxide films Ma and silicon nitride films Mb are not etched or are hardly etched by the processing liquid L.

The principal surface Wa is an outermost surface of the laminated structure M. The recess portion Wb, for example, penetrates through the laminated structure M in a lamination direction (Y direction). The recess portion Wb, for example, is of a circular columnar shape. The recess portion Wb is not restricted to being of the circular columnar shape and, for example, may be of a polygonal columnar shape or may be of an elliptical columnar shape. Here, if the recess portion Wb is of a shape having a long direction and a short direction (for example, an elliptical shape, an oval shape, or a rectangular shape) when viewed from the lamination direction (Y direction), a length in the short direction with respect to a length in the long direction is preferably not more than 2. Also, an aspect ratio of the recess portion Wb is, for example, not less than 5 and not more than 500. The aspect ratio is a ratio of a depth and a hole diameter of the recess portion Wb. Also, although in the figures, the silicon oxide films Ma and silicon nitride films Mb are exposed at an inner side surface of the recess portion Wb, the inner side surface of the recess portion Wb may instead be covered, for example, by a silicon oxide film or a silicon nitride film.

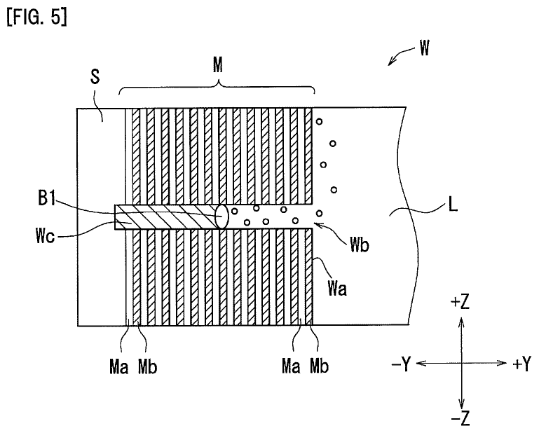

Next, bubbles that are generated when the substrate W is immersed in the processing liquid L shall be described with reference to FIG. 4 and FIG. 5. FIG. 4 is an enlarged sectional view schematically showing a state in which bubbles are generated inside the recess portion Wb. FIG. 5 is an enlarged sectional view schematically showing a state in which the bubbles generated inside the recess portion Wb become enlarged. As shown in FIG. 4, when the substrate W is immersed in the processing liquid L, the polysilicon layer Wc is etched by the processing liquid L. In this process, hydrogen is produced inside the recess portion Wb and bubbles are generated inside the processing liquid L. As shown in FIG. 5, the generated bubbles are released to an exterior from the recess portion Wb or the generated bubbles join together to become large. In FIG. 4, an enlarged bubble is provided with a reference sign “B1.”

Here, in this preferred embodiment, since the recess portion Wb of the substrate W is large in aspect ratio and is of columnar shape, the enlarged bubble tends to become clogged in the recess portion Wb. That is, when the bubble enlarges to become approximately equal to a cross-sectional area of the recess portion Wb, the processing liquid L becomes unable to move to the polysilicon layer Wc side and therefore, the bubble becomes unlikely to be released from the recess portion Wb. The etching of the polysilicon layer Wc thus stops progressing. Here, even if the aspect ratio of the recess portion Wb is large, if the recess portion Wb is, for example, of a groove shape or slit shape when viewed in a direction (the Y direction) perpendicular to a surface of the polysilicon layer Wc, the bubbles are less likely to become clogged in the recess portion Wb.

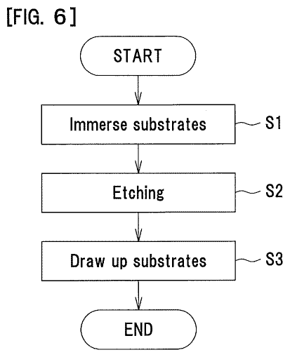

Next, a substrate processing method according to the first preferred embodiment of the present invention shall be described with reference to FIG. 6. FIG. 6 is a flowchart showing the substrate processing method according to the first preferred embodiment. As shown in FIG. 6, the substrate processing method includes step S1 to step S3. Step S1 to step S3 are executed by the substrate processing apparatus 100.

In step S1, the controlling portion 11 makes the substrate holding portion 120 holding the substrates W move vertically downward. The substrates W are thereby immersed in the processing liquid L. In other words, the controlling portion 11 immerses the substrates W held by the substrate holding portion 120 in the processing liquid L such that the polysilicon layers Wc are etched by the processing liquid L. Here, step S1 is an example of an “immersion step” of the present invention.

Next, in step S2, the polysilicon layers Wc filled in the recess portion Wb of the substrates W are etched by the processing liquid L. Then, when the polysilicon layers Wc inside the recess portion portions Wb are eliminated, step S3 is entered. Here, step S2 is an example of an “etching step” of the present invention.

Next, in step S3, the controlling portion 11 makes the substrate holding portion 120 holding the substrates W move vertically upward. The substrates W are thereby drawn out from the processing liquid L.

The processing of the substrates W is thus ended. Also, after step S3, a step of cleaning the substrates W with a cleaning liquid, a step of drying the substrates W, etc., may be executed by the substrate processing apparatus 100 or other apparatus.

In this preferred embodiment, the bubbles generated inside each recess portion Wb are removed in step S2. Also, in step S2, the bubbles generated inside the recess portion Wb are removed in accordance with the silicon concentration in the processing liquid L. These shall now be described specifically.

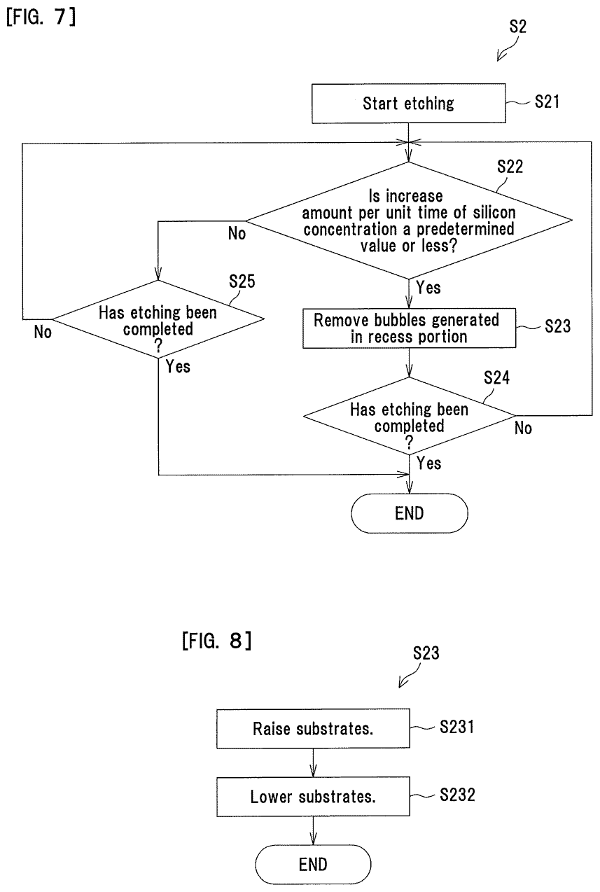

Next, step S2 shall be described in detail with reference to FIG. 7. FIG. 7 is a flowchart for describing step S2 in detail. As shown in FIG. 7, in this preferred embodiment, step S2 includes step S21 to step S25.

In step S21, the etching of the polysilicon layer Wc by the processing liquid L is started. The bubbles are thereby generated inside the recess portion Wb. Also, the silicon concentration contained in the processing liquid L increases with progress of the etching of the polysilicon layer Wc.

Next, in step S22, the controlling portion 11 determines whether or not the increase amount per unit time of the silicon concentration of the processing liquid L has become a predetermined value or less. Here, in this preferred embodiment, the controlling portion 11 makes the determination using the silicon concentration detected by the concentration meter 190. Here, when the processing liquid L etches the polysilicon layer Wc, the bubbles are generated inside the recess portion Wb. When the bubbles generated inside the recess portion Wb enlarge and becomes clogged in the recess portion Wb, the silicon stops dissolving in the processing liquid L and the increase amount per unit time of the silicon concentration decreases. That is, in step S22, the controlling portion 11 determines whether or not clogging occurs in the recess portion Wb due to the bubbles generated by etching.

If in step S22, the controlling portion 11 determines that the increase amount per unit time of the silicon concentration has become the predetermined value or less, the processing enters step S23.

Next, in step S23, the bubbles generated inside the recess portion Wb are removed from inside the recess portion Wb. In this preferred embodiment, the bubbles that have become clogged in the recess portion Wb are removed.

Next, in step S24, the controlling portion 11 determines whether or not the etching of the polysilicon layer We has been completed. For example, the controlling portion 11 determines whether or not the etching of the polysilicon layer Wc has been completed by determining whether or not a processing time of a predetermined time or more has elapsed. The predetermined time is, for example, an elapsed time from step S21. The predetermined time may be set in advance in consideration of, for example, a reaction time of the processing liquid L and the polysilicon layer Wc, a time required for step S23, etc. Also, the controlling portion 11 may determine whether or not the etching of the polysilicon layer Wc has been completed by determining whether or not the silicon concentration in the processing liquid L has increased by a predetermined amount or more. In this case, the predetermined amount may be set in advance in consideration of, for example, a volume and a number of the polysilicon layers Wc.

If in step S24, the controlling portion 11 determines that the etching of the polysilicon layer Wc has been completed, step S2 ends.

On the other hand, if in step S24, it is determined that the etching of the polysilicon layer Wc has not been completed, a return to S22 is performed.

If in step S22, the controlling portion 11 determines that the increase amount per unit time of the silicon concentration has not become the predetermined value or less, the processing enters step S25.

Next, in step S25, the controlling portion 11 determines whether or not the etching of the polysilicon layer Wc has been completed. For example, the controlling portion 11 determines whether or not the etching of the polysilicon layer Wc has been completed by determining whether or not the processing time of a predetermined time or more has elapsed. The predetermined time is, for example, the elapsed time from step S21. The predetermined time may be set in advance in consideration of, for example, the reaction time of the processing liquid L and the polysilicon layer Wc, the time required for step S23, etc. The predetermined time of step S25 may be shorter than the predetermined time of step S24. However, the predetermined time of step S25 may be the same as the predetermined time of step S24. Also, the controlling portion 11 may determine whether or not the etching of the polysilicon layer Wc has been completed by determining whether or not the silicon concentration in the processing liquid L has increased by a predetermined amount or more. In this case, the predetermined amount may be set in advance in consideration of, for example, the volume and the number of the polysilicon layers Wc. The predetermined amount of step S25, though not restricted in particular, is the same as the predetermined amount of step S24.

If in step S25, the controlling portion 11 determines that the etching of the polysilicon layer Wc has been completed, step S2 ends.

On the other hand, if in step S25, it is determined that the etching of the polysilicon layer Wc has not been completed, the processing returns to step S22.

As described above with reference to FIG. 1 to FIG. 7, the substrate processing method of this preferred embodiment includes step S1 of immersing the substrate W in the processing liquid L and step S2 of etching the polysilicon layer Wc by the processing liquid L and in step S2, the bubbles generated in the recess portion Wb are removed. Since the etching of the polysilicon layer Wc can therefore be suppressed from not being completed, occurrence of etching failure can be suppressed.

Also, as described above, in step S2, the bubbles generated in the recess portion Wb are removed in accordance with the silicon concentration in the processing liquid L. Therefore, for example, when clogging occurs in the recess portion Wb due to the bubbles, the bubbles generated inside the recess portion Wb can be removed. Removal of the bubbles can thus be performed efficiently.

Also, although with this preferred embodiment, an example where the bubbles generated inside the recess portion Wb are removed based on the silicon concentration detected by the concentration meter 190, the present invention is not limited thereto. For example, a relationship between the increase amount per unit time of the silicon concentration of the processing liquid L and an etching time may be acquired in advance and step S23 may be executed when a predetermined time elapses. This case is also equivalent to removing the bubbles generated inside the recess portion Wb in accordance with the silicon concentration in the processing liquid L.

Also as described above, the bubbles clogged in the recess portion Wb are removed in step S2. The bubbles generated inside the recess portion Wb can thus be removed, for example, only when clogging occurs in the recess portion Wb due to the bubbles. Also, instead of removing the bubbles after the bubbles become clogged in the recess portion Wb, the bubbles may be removed when the bubbles are about to become clogged in the recess portion Wb.

Also, as described above, the processing liquid L contains tetramethylammonium hydroxide. Therefore, an etching rate with respect to the polysilicon layer Wc can be made high.

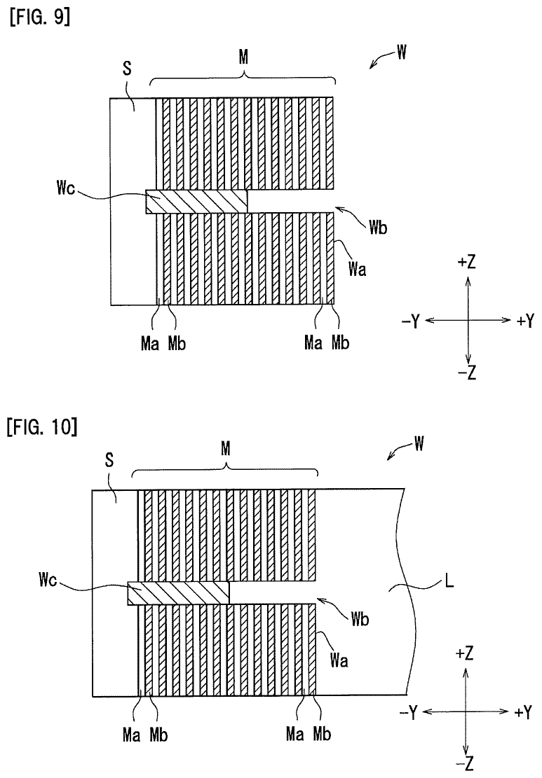

Next, step S23 shall be described in detail with reference to FIG. 8 to FIG. 10. FIG. 8 is a flowchart for describing step S23 in detail. FIG. 9 is an enlarged sectional view schematically showing a state in which the processing liquid L has been drained from inside the recess portion Wb. FIG. 10 is an enlarged sectional view schematically showing a state in which the processing liquid L has flowed into the recess portion Wb. As shown in FIG. 8, in this preferred embodiment, step S23 includes step S231 and step S232.

In step S231, the controlling portion 11 makes the substrate holding portion 120 holding the substrates W move vertically upward. That is, the controlling portion 11 raises the substrates W. The substrates W are thereby drawn out from the processing liquid L. In this process, the processing liquid L in each recess portion Wb is released as shown in FIG. 9.

Next, in step S232, the controlling portion 11 makes the substrate holding portion 120 holding the substrates W move vertically downward. That is, the controlling portion 11 lowers the substrates W. The substrates W are thereby immersed in the processing liquid L. In this process, the processing liquid L is filled into each recess portion Wb as shown in FIG. 10. Here, a gas inside the recess portion Wb is released when the substrate W is immersed in the processing liquid L. Specifically, an inner surface of the recess portion Wb is hydrophilic and thus the processing liquid L flows in readily. Also, when the substrate W is immersed in the processing liquid L, the processing liquid L is fast in flow at a surface of the substrate W and is high in fluidity and therefore, the gas inside the recess portion Wb is released to the exterior without staying inside the recess portion Wb. The etching by the processing liquid L is then restarted and step S23 ends.

As described above with reference to FIG. 8 to FIG. 10, with the substrate processing method of this preferred embodiment, the processing liquid L and the bubbles are removed from inside each recess portion Wb by drawing up each substrate W from the processing tank 110 in step S2. The bubbles can thus be removed easily from inside the recess portion Wb.

### First Modification Example

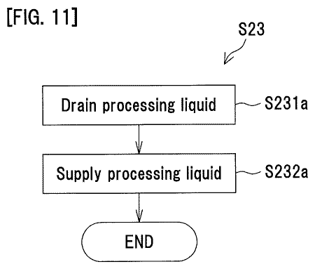

Next, a first modification example of the first preferred embodiment shall be described with reference to FIG. 11. FIG. 11 is a flowchart for describing step S23 of a substrate processing method of the first modification example of the first preferred embodiment in detail. With the first modification example, an example in which a specific method of step S23 differs from the substrate processing method of the first preferred embodiment described using FIG. 8 shall be described.

As shown in FIG. 11, in the first modification example, step S23 includes step S231a and step S232a.

In step S231a, the controlling portion 11 drains the processing liquid L of the processing tank 110. Specifically, the controlling portion 11 opens the valve 174 of the draining portion 170. The processing liquid L inside each recess portion Wb is thereby released as shown in FIG. 9.

Next, in step S232a, the controlling portion 11 supplies the processing liquid L to the processing tank 110. Specifically, the controlling portion 11 controls the processing liquid supplying portion 150 to supply the processing liquid L to the processing tank 110. The substrates W are thereby immersed in the processing liquid L. In this state, the interior of each recess portion Wb is filled with the processing liquid L as shown in FIG. 10. The etching by the processing liquid L is then restarted and step S23 ends.

Other arrangements and other substrate processing methods of the first modification example are the same as those of the first preferred embodiment.

As described above with reference to FIG. 11, with the substrate processing method of the first modification example, the processing liquid L and the bubbles are removed from inside the recess portion Wb by the processing liquid L being drained from the processing tank 110 in step S2. The bubbles can thus be removed easily from inside the recess portion Wb.

### Second Preferred Embodiment

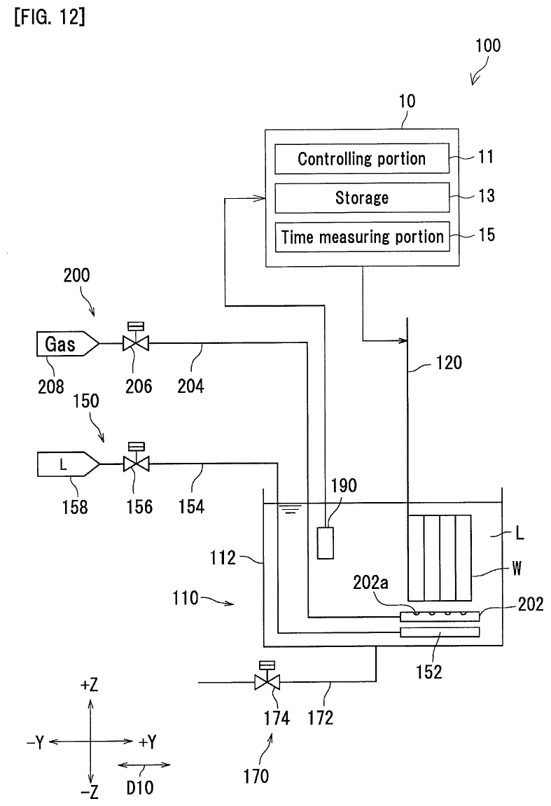

A substrate processing apparatus 100 and a substrate processing method according to a second preferred embodiment of the present invention shall be described with reference to FIG. 12 to FIG. 14. With the second preferred embodiment, an example where the bubbles generated inside each recess portion Wb are removed from the recess portion Wb by generating bubbles below the substrates W shall be described. Points by which the second preferred embodiment differs from the first preferred embodiment shall mainly be described below.

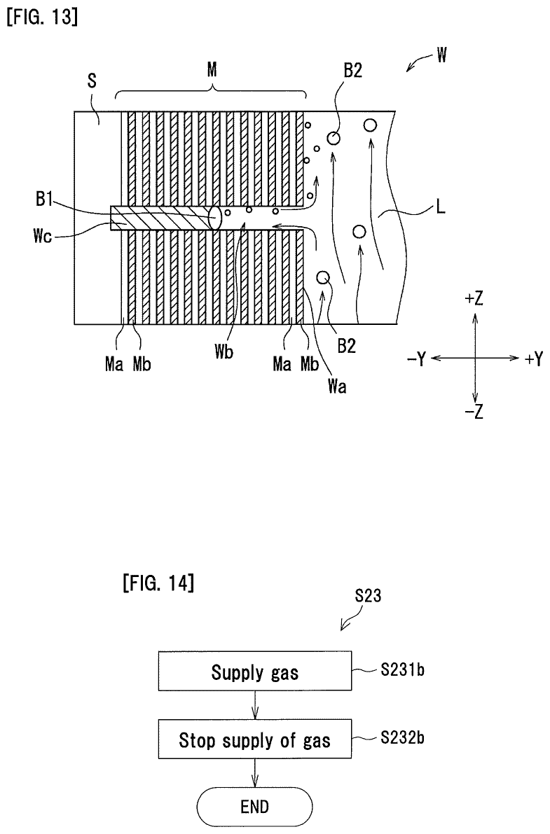

First, the substrate processing apparatus 100 according to the second preferred embodiment shall be described with reference to FIG. 12 and FIG. 13. FIG. 12 is a schematic view showing the structure of the substrate processing apparatus 100 according to the second preferred embodiment of the present invention. As shown in FIG. 12, the substrate processing apparatus 100 further includes a bubble generating portion 200. The bubble generating portion 200 generates bubbles inside the processing liquid L by supplying a gas into the processing liquid L. The bubble generating portion 200 includes a nozzle 202, a piping 204, a valve 206, and a gas supply source 208. The bubble generating portion 200 is controlled by the controlling portion 11.

The nozzle 202 supplies the gas into the processing liquid L. The gas is thereby generated inside the processing liquid L. The gas supplied into the processing liquid L is not restricted in particular and is, for example, nitrogen gas. Also, the nozzle 202 is disposed below the substrates W. The gas is thus supplied below the substrates W.

The nozzle 202 is connected to the piping 204. The gas from the gas supply source 208 is supplied to the piping 204. The valve 206 is disposed in the piping 204. The valve 206 opens and closes the piping 204. When the valve 206 is opened, the gas is supplied into the processing liquid L from the gas supply source 208 via the piping 204. The valve 206 is not restricted in particular and may, for example, be a control valve capable of controlling a flow rate of the gas. Also, the bubble generating portion 200 may include a flowmeter (not shown) that measures the flow rate of the gas. In this case, the flowmeter may transmit a measurement result to the controlling portion 11.

Next, the nozzle 202 shall be described. The nozzle 202 generates a plurality of bubbles (a large number of bubbles) inside the processing liquid L and supplies the bubbles toward the substrates W immersed in the processing liquid L. The nozzle 202 is, for example, a bubbler.

The nozzle 202 has a substantially cylindrical shape. The nozzle 202 extends in the first direction D10. Although just one nozzle 202 is drawn in FIG. 12, a plurality thereof are disposed in the X direction.

Each nozzle 202 has a plurality of supply holes 202a that supply the gas into the processing liquid L. The supply hole 202a is, for example, of a circular shape. A hole diameter of the supply hole 202a is, for example, of the order of several ten μm to several hundred μm. For example, several ten supply holes 202a are provided in a single nozzle 202. The plurality of supply holes 202a are disposed at a predetermined pitch in the first direction D10. Also, the plurality of supply holes 202a may be disposed at equal intervals or may be disposed at unequal intervals in the first direction D10.

When the valve 206 is opened, bubbles B2 are generated in the processing liquid L. Hereinafter, the bubbles generated by the bubble generating portion 200 shall be referred to as the bubbles B2.

FIG. 13 is an enlarged sectional view schematically showing flows of the processing liquid L and the bubbles in a periphery of a recess portion Wb. As shown in FIG. 13, the bubbles B2 have a diameter, for example, greater than 100 μm. The bubbles B2 preferably have a diameter, for example, of approximately several hundred μm to several mm. Comparatively large buoyant forces thus act on the bubbles B2. Flows of the processing liquid L in the upward direction are thus generated due to rise of the bubbles B2 in peripheries of the substrates W. Then, due to increase in fluidity of the processing liquid L, inflow and release of the processing liquid L are promoted in the recess portion Wb. Release efficiency of the bubbles generated inside the recess portion Wb is thus improved. Also, in this state, the bubble B1 that enlarged inside the recess portion Wb becomes split due to the flow of the processing liquid L and is released from the recess portion Wb.

Next, step S23 of the substrate processing method according to the second preferred embodiment of the present invention shall be described with reference to FIG. 14. FIG. 14 is a flowchart for describing step S23 of the substrate processing method of the second preferred embodiment of the present invention in detail. As shown in FIG. 14, in this preferred embodiment, step S23 includes step S231b and step S232b.

In step S231b, the controlling portion 11 controls the bubble generating portion 200 such as to supply the gas below the substrates W and generate bubbles inside the processing liquid L. That is, the controlling portion 11 opens the valve 206 and makes the bubbles B2 be generated inside the processing liquid L. Thereby, flows of the processing liquid L in the upward direction due to rise of the bubbles B2 are generated in the peripheries of the substrates W as described above. The release efficiency of the bubbles generated inside each recess portion Wb is then improved. Also, the bubble B1 that enlarged inside the recess portion Wb becomes split due to the flow of the processing liquid L and is released from the recess portion Wb. Consequently, the etching by the processing liquid L is restarted.

Next, in step S232b, the controlling portion 11 controls the bubble generating portion 200 such as to stop the supply of the gas into the processing liquid L. That is, the controlling portion 11 closes the valve 206 and stops the generation of the bubbles B2 inside the processing liquid L. Step S23 then ends.

Other arrangements and other substrate processing methods of the second preferred embodiment are the same as those of the first preferred embodiment.

As described above with reference to FIG. 12 to FIG. 14, with the substrate processing method of the second preferred embodiment, the bubbles generated inside each recess portion Wb is removed by supplying the gas below each substrate W and generating bubbles inside the processing liquid L in step S2. The bubbles can thus be removed easily from inside the recess portion Wb.

Also, by stopping the supply of the gas into the processing liquid L in step S232b as described above, a consumption amount of the gas (here, nitrogen gas) can be reduced. That is, an environmental load can be reduced.

Other effects of the second preferred embodiment are the same as those of the first preferred embodiment.

### Third Preferred Embodiment

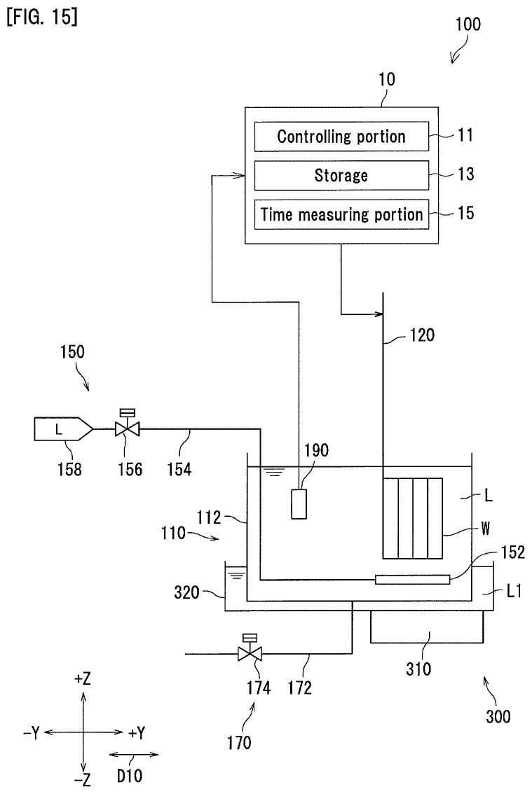

A substrate processing apparatus 100 and a substrate processing method according to a third preferred embodiment of the present invention shall be described with reference to FIG. 15 to FIG. 18. With the third preferred embodiment, an example where the bubbles generated inside each recess portion Wb are removed from the recess portion Wb by applying an ultrasonic vibration to the processing liquid L shall be described. Points by which the third preferred embodiment differs from the first preferred embodiment shall mainly be described below.

First, the substrate processing apparatus 100 according to the third preferred embodiment shall be described with reference to FIG. 15. FIG. 15 is a schematic view showing the structure of the substrate processing apparatus 100 according to the third preferred embodiment of the present invention. As shown in FIG. 15, the substrate processing apparatus 100 further includes an ultrasonic generating portion 300.

The ultrasonic generating portion 300 applies an ultrasonic vibration to the processing liquid L. Specifically, the ultrasonic generating portion 300 includes an ultrasonic vibration element 310 and a propagation tank 320. The ultrasonic vibration element 310 generates the ultrasonic vibration. A vibration frequency of the ultrasonic vibration element 310 is, for example, several ten kHz to several MHz. The vibration frequency of the ultrasonic vibration element 310 is preferably, for example, several hundred kHz to 1 MHz. Also, the ultrasonic vibration element 310 is controlled by the controlling portion 11.

The propagation tank 320 is provided to propagate the ultrasonic vibration, generated by the ultrasonic vibration element 310, to the substrates W. The propagation tank 320 houses a lower portion of the processing tank 110. The propagation tank 320 stores a propagation liquid L1. The propagation liquid L1 is stored in the propagation tank 320 such as to contact the lower portion of the processing tank 110. The propagation liquid L1 is not restricted in particular and is, for example, pure water.

When the ultrasonic vibration element 310 is driven, the generated ultrasonic vibration propagates to the substrates W via the propagation tank 320, the propagation liquid L1, the processing tank 110, and the processing liquid L.

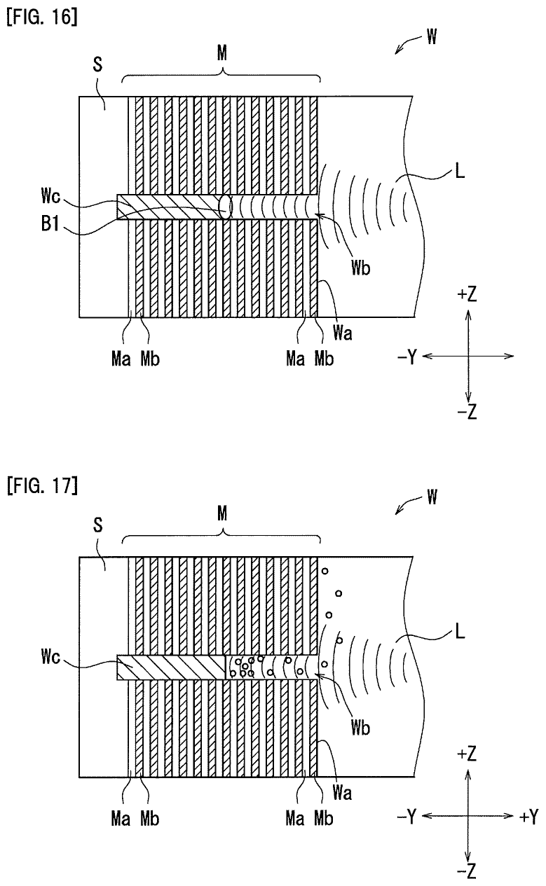

FIG. 16 is an enlarged sectional view schematically showing a state in which the ultrasonic vibration propagates in a periphery of a recess portion Wb. FIG. 17 is an enlarged sectional view schematically showing a state in which the bubble B1 is split by the ultrasonic vibration in the periphery of the recess portion Wb. When the ultrasonic vibration element 310 is driven, bubbles of a micrometer order are generated inside the processing liquid L due to cavitation. On the other hand, for example, the large bubble B1 shown in FIG. 16 is split by the ultrasonic vibration as shown in FIG. 17. The split bubbles are then released from the recess portion Wb. Here, due to the ultrasonic vibration by the ultrasonic vibration element 310, the bubbles are split to a size of not more than a predetermined size.

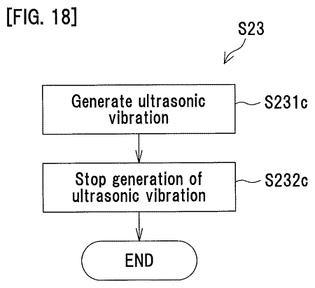

Next, step S23 of the substrate processing method according to the third preferred embodiment of the present invention shall be described with reference to FIG. 18. FIG. 18 is a flowchart for describing step S23 of the substrate processing method of the third preferred embodiment of the present invention in detail. As shown in FIG. 18, in this preferred embodiment, step S23 includes step S231c and step S232c.

In step S231c, the controlling portion 11 controls the ultrasonic generating portion 300 such as to apply the ultrasonic vibration to the processing liquid L. That is, the controlling portion 11 drives the ultrasonic vibration element 310 to make the ultrasonic vibration propagate to the processing liquid L and the substrate W. Thereby, large bubbles B1 such that become clogged in the recess portion portions Wb are split by the ultrasonic vibration as described above. Also, bubbles that are smaller than the bubbles B1 but larger than the predetermined size are also split by the ultrasonic vibration. The split bubbles are released from the recess portion portions Wb. Consequently, the etching by the processing liquid L is restarted. Also, by the splitting of the bubbles B1, the processing liquid L contacts the polysilicon layers Wc. The etching by the processing liquid L is restarted thereby as well.

Next, in step S232c, the controlling portion 11 controls the ultrasonic generating portion 300 such as to stop the generation of the ultrasonic vibration. That is, the controlling portion 11 stops the driving of the ultrasonic vibration element 310 and stops the generation of the ultrasonic vibration. Step S23 then ends.

Other arrangements and other substrate processing methods of the third preferred embodiment are the same as those of the first preferred embodiment.

As described above with reference to FIG. 15 to FIG. 18, with the substrate processing method of the third preferred embodiment, the bubbles generated inside each recess portion Wb is removed by applying the ultrasonic vibration to the processing liquid L in step S2. The bubbles can thus be removed easily from inside the recess portion Wb.

Also, by stopping the generation of the ultrasonic vibration in step S232c as described above, a time during which a load is applied to patterns (not shown) formed on the substrates W can be shortened. Application of adverse influences on the patterns (not shown) of the substrates W can thus be suppressed.

Other effects of the third preferred embodiment are the same as those of the first preferred embodiment.

Preferred Embodiments of the Present Invention have been described above with reference to the drawings. However, the present invention is not limited to the preferred embodiments described above and can be implemented in various modes within a scope not deviating from its gist. Also, it is possible to form various inventions by suitably combining a plurality of constituent elements disclosed in the preferred embodiments described above. For example, some constituent elements may be deleted from the total of constituent elements indicated in the preferred embodiments. Further, constituent elements across different preferred embodiments may be combined as suited. The drawings mainly illustrate the respective constituent elements schematically for ease of understanding and there are cases where thicknesses, lengths, numbers, intervals, etc., of the respective constituent elements illustrated differ from actuality due to convenience of drawing preparation. Also, the material, shape, dimensions, etc., of the respective constituent elements indicated in the preferred embodiments described above are but an example, are not restricted in particular, and can be changed variously within a scope of practically not deviating from the effects of the present invention.

For example, although with the second preferred embodiment and the third preferred embodiment described above, an example of removing the bubbles in accordance with the silicon concentration in the processing liquid L was described, the present invention is not limited thereto. For example, in the second preferred embodiment, bubbles may be generated below the substrates W regardless of the silicon concentration in an entire period of step S2 or in an entire period of step S1 to S3. Also, for example, in the third preferred embodiment, the ultrasonic vibration may be applied to the processing liquid L regardless of the silicon concentration in an entire period of step S2 or in an entire period of step S1 to S3. That is, the bubbles may be removed from before the bubbles become clogged in the recess portion portions Wb.

### INDUSTRIAL APPLICABILITY

The present invention relates to a substrate processing apparatus and a substrate processing method and has industrial applicability.

### REFERENCE SIGNS LIST

11: controlling portion
100: substrate processing apparatus
110: processing tank
120: substrate holding portion
200: bubble generating portion
300: ultrasonic generating portion
B1, B2: bubble
L: processing liquid
S1: step (immersion step)
S2: step (etching step)
W: substrate
Wa: principal surface
Wb: recess portion
Wc: polysilicon layer

1. A substrate processing method comprising:
immersing a substrate in an alkaline processing liquid; and
etching, by the alkaline processing liquid, a polysilicon layer filled in a recess portion of columnar shape extending substantially perpendicular to a principal surface of the substrate;
wherein in etching the polysilicon layer, bubbles generated inside the recess portion are removed.

2. The substrate processing method according to claim 1, wherein in etching the polysilicon layer, the bubbles generated inside the recess portion are removed in accordance with a silicon concentration in the alkaline processing liquid.

3. The substrate processing method according to claim 1, wherein in etching the polysilicon layer, the bubbles clogged in the recess portion are removed.

4. The substrate processing method according to claim 1, wherein in etching the polysilicon layer, the alkaline processing liquid and the bubbles are removed from inside the recess portion by draining the alkaline processing liquid from a processing tank storing the alkaline processing liquid or drawing up the substrate from the processing tank.

5. The substrate processing method according to claim 1, wherein in etching the polysilicon layer, the bubbles generated inside the recess portion are removed by supplying a gas below the substrate and generating bubbles inside the alkaline processing liquid.

6. The substrate processing method according to claim 1, wherein in etching the polysilicon layer, the bubbles generated inside the recess portion are removed by applying an ultrasonic vibration to the alkaline processing liquid.

7. The substrate processing method according claim 1, wherein the alkaline processing liquid contains tetramethylammonium hydroxide.

8. A substrate processing apparatus comprising:
a substrate holder to hold at least one substrate;
a processing tank to store an alkaline processing liquid for immersing the substrate held by the substrate holder; and
a controller;
wherein the substrate includes a principal surface, a recess portion of columnar shape extending substantially perpendicular to the principal surface, and a polysilicon layer filled in the recess portion, and
the controller is configured or programmed
to immerse the substrate, held by the substrate holder, in the alkaline processing liquid such that the polysilicon layer is etched by the alkaline processing liquid, and
to remove bubbles generated inside the recess portion.

9. The substrate processing apparatus according to claim 8, wherein the controller is configured or programmed to remove the bubbles, generated inside the recess portion, in accordance with a silicon concentration in the alkaline processing liquid.

10. The substrate processing apparatus according to claim 8, wherein the controller is configured or programmed to remove the bubbles clogged in the recess portion.

11. The substrate processing apparatus according to claim 8, wherein the controller is configured or programmed to drain the alkaline processing liquid from the processing tank or to draw up the substrate from the processing tank so as to remove the alkaline processing liquid and the bubbles from inside the recess portion.

12. The substrate processing apparatus according to claim 8, further comprising: a bubble generator to supply a gas to the alkaline processing liquid and bubbles be generated in the alkaline processing liquid;
wherein the controller is configured or programmed to control the bubble generator such that the gas is supplied below the substrate and the bubbles are generated inside the alkaline processing liquid.

13. The substrate processing apparatus according to claim 8, further comprising: an ultrasonic generator to apply an ultrasonic vibration to the alkaline processing liquid;
wherein the controller is configured or programmed to control the ultrasonic generator to apply the ultrasonic vibration to the alkaline processing liquid.

14. The substrate processing apparatus according to claim 8, wherein the alkaline processing liquid contains tetramethylammonium hydroxide.
